(19) United States
(12) Patent Application Publication
(10) Pub. No.: US 2004/0146131 A1
(43) Pub. Date: Jul. 29, 2004

(54) Phase detector

(75) Inventor: Paul Wilson, Bristol (GB)

Correspondence Address: LAHIVE & COCKFIELD, LLP., 28 STATE STREET, BOSTON, MA, 02109, US

(73) Assignee: Phyworks Limited, Bristol (GB)

(21) Appl. No.: 10/379,745

(22) Filed: Mar. 5, 2003

(30) Foreign Application Priority Data
Jan. 29, 2003 (GB) 0302089.8

(51) Int. Cl. H03D 3/24

(52) U.S. Cl. 375/375

(57) ABSTRACT

A clock recovery circuit includes a limiting amplifier to speed up transitions in input data. The resulting input data stream is supplied to a phase detector, which produces a modified input data stream, having data transitions corresponding to alternate input data transitions. The phase detector includes logic circuitry, for producing phase alignment pulses, whose duration is dependent on the time period from a modified data transition, which occurs while the clock signal takes the first value, until a clock signal transition from the second value to the first value. The phase detector also includes an output device, for comparing the duration of the phase alignment pulses with the duration of pulses in the clock signal.

### TECHNICAL FIELD OF THE INVENTION

This invention relates to a phase detector, and in particular to a phase detector for use in a clock recovery circuit in a communications device.

### BACKGROUND OF THE INVENTION

In communications networks, data is transmitted over a communications medium, for example a copper wire or an optical fibre. The data is transmitted in the form of a signal which, in the case of a copper wire, may be a voltage level, and, in the case of an optical fibre, may be a light intensity. The signal forms a series of binary pulses, each representing one bit in the original data. That is, the transmitted signal takes either a first value, representing a binary 0 in the data stream, or a second value, representing a binary 1 in the data stream.

The signal is distorted by the communications medium. For example, in the case of an optical fibre, different frequency components of the transmitted signal can travel through the fibre at different speeds. This gives rise to inter-symbol-interference (ISI), in which each pulse effectively spreads over a slightly longer time period. Also, noise is added to the signal. The result is that, at the receiving device, the resulting signal is a distorted version of the transmitted signal.

The function of the receiving device is to recreate the original data stream as closely as possible. In order to be able to achieve this, it is first necessary to sample the resulting signal at regular intervals, corresponding to the durations of the pulses in the transmitted signal. It is also necessary for these sampling points to be such that the resulting sampled values form a data stream which resembles as closely as possible the transmitted data stream. In most cases, this sampling should therefore occur in the centre of each pulse, although the distortion of the received signal means that it is not straightforward to determine when this occurs.

The document “A 10-Gb/s CMOS Clock and Data Recovery Circuit with a Half-Rate Linear Phase Detector”, Savoj, et al, IEEE Journal of Solid-State Circuits, vol. 36, no. 5, May 2001, describes a circuit in which the phase of the incoming data is compared with a half-rate clock. However, this circuit generates and processes very short pulses which, at the high data rates required, can be heavily distorted, resulting in poor performance of the device.

### SUMMARY OF THE INVENTION

The present invention provides a phase detector, having:

an input; for receiving an input data stream, the input data stream having input data transitions;

a divider, for producing a modified input data stream, the modified input data stream having modified input data transitions, and the modified input data transitions corresponding to alternate input data transitions;

a clock signal input, the clock signal alternately taking first and second values, and having clock signal transitions therebetween;

circuitry for producing a phase dependent output, which is representative of the time period from a modified data transition, which occurs while the clock signal takes the first value, until a clock signal transition from the second value to the first value; and

an output device, for comparing the phase dependent output with the duration of pulses in the clock signal.

This phase detector circuit has the advantage that the circuitry for producing the phase dependent output has to handle signals with a comparatively low frequency content, reducing the likelihood of distortion in the signals.

Other aspects of the invention relate to a clock recovery circuit including the phase detector, and a receiver which incorporates the clock recovery circuit.

### BRIEF DESCRIPTION OF DRAWINGS

FIG. 1 is a block schematic diagram of a communications system including a receiver in accordance with an aspect of the invention.

FIG. 2 is a timing diagram illustrating a feature of a signal at a point in the receiver of the present invention.

FIG. 3 is a more detailed block schematic diagram of a part of the receiver in accordance with an aspect of the invention.

FIG. 4 is a block schematic diagram of a part of the receiver in accordance with an aspect of the invention.

FIG. 5 is a block schematic diagram showing the phase detector of the present invention.

FIG. 6 is a further block schematic diagram showing the operation of a part of the phase detector of FIG. 5.

FIG. 7 is a further more detailed block schematic diagram of the phase detector in accordance with an aspect of the invention.

FIG. 8 is a timing diagram showing signals at points in the circuit of FIG. 7.

FIG. 9 is another timing diagram showing another example of signals at points in the circuit of FIG. 7.

### DETAILED DESCRIPTION OF PREFERRED EMBODIMENTS

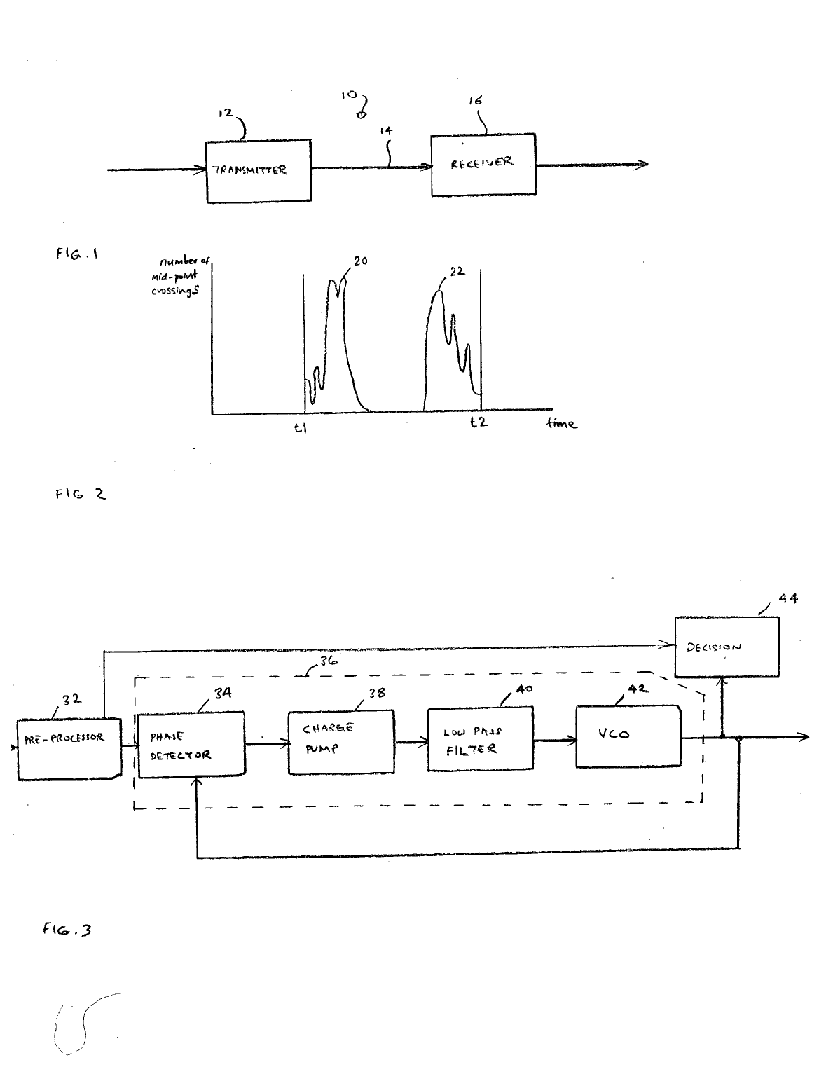

FIG. 1 is a block schematic diagram of a communications system 10, made up of a transmitter 12, a communications medium 14, and a receiver 16. In this illustrative example, the communications medium 14 is an optical fibre. The transmitter 12 receives input data, and converts it into a format which is suitable for transmission over the communications medium. In particular, the transmitter generates a signal which includes a series of binary pulses, each representing one bit in the original data. The transmitted signal can take either a first value, representing a binary 0 in the data stream, or a second value, representing a binary 1 in the data stream. Where the communications medium 14 is an optical fibre, the transmitted signal may for example include pulses at a data rate of 10 Gb/s. The duration of a pulse is referred to herein as a unit interval (UI).

The function of the receiver 16 is to receive the signal after transmission over the communications medium, and to recreate as closely as possible the original data stream, despite the effects of noise and distortion which will inevitably occur in the course of such transmission.

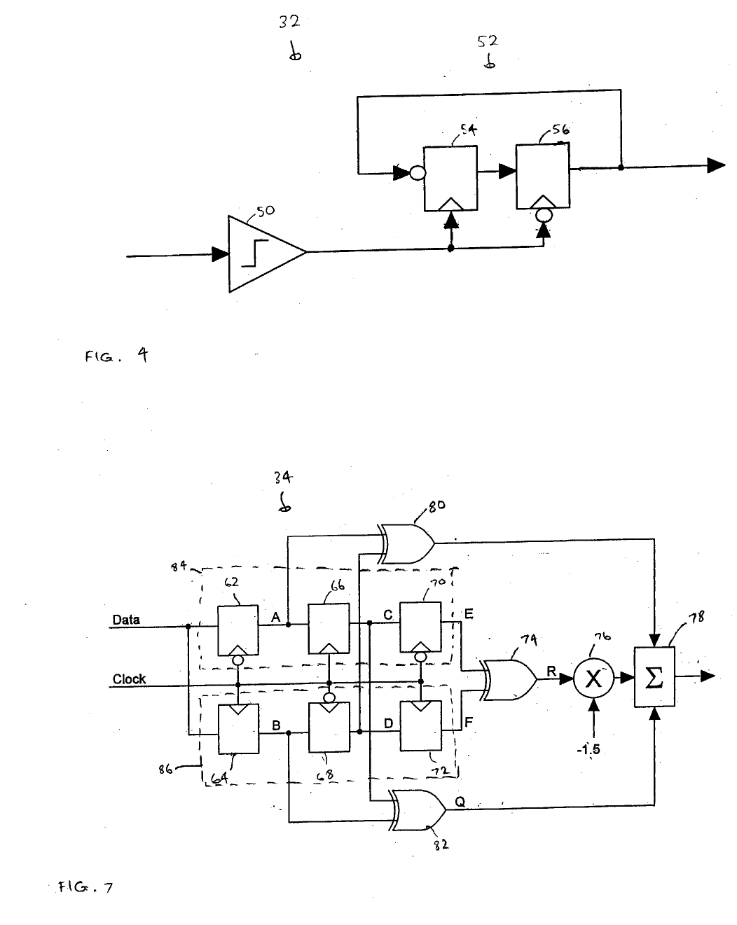

FIG. 2 illustrates a feature of the signal which is received in the receiver 16. Specifically, the signal that is transmitted over the communications medium 14 contains components at different frequencies, and the optical fibre material is a dispersive medium. That is, different frequency components travel through the fibre at slightly different speeds, and hence take slightly different times to travel to the receiver. One result of this is that the pulses in the transmitted signal are distorted when they reach the receiver. In effect, each pulse is slightly spread out over a longer time period. Also, noise is added to the signal.

FIG. 2 shows the effect of these factors. In FIG. 2, the time t1 represents the start of an ideal pulse, and time t2 represents the end of that ideal pulse. However, the reality differs from this ideal situation. The line 20 shows, for times between t1 and t2, the number of occasions on which it is actually observed that the signal value crosses a mid-point value (for example, the long-term average of the signal value), when it is increasing from a low value to a high value. It can be seen that this occurs over a range of times, but that the average time is significantly later than the ideal time t1. Somewhat similarly, the line 22 shows, for times between t1 and t2, the number of occasions on which it is actually observed that the signal value crosses the mid-point value, when it is decreasing from a high value to a low value. Again it can be seen that this occurs over a range of times, but in this case the average time is significantly earlier than the ideal time t2.

The effect of this is that data is in the received signal have a duration which is, on average, significantly shorter than data Os. This feature is described as “duty cycle distortion”.

Also, the spreading effect, described above, means that each transition, either from a data “1” to a data “0”, or vice versa, occurs over a significant time period.

FIG. 3 is a block schematic diagram of a clock recovery circuit 30, which forms part of the receiver 16. The received signal, incorporating the forms of distortion described above, is passed to a preprocessing unit 32. The preprocessed signal is then passed to a phase detector 34, which forms part of a phase-locked loop 36. The form of the phase locked loop 36 is broadly conventional. The phase detector 34 receives at its second input a clock signal, and it provides an output which represents the phase difference between its two input signals. This output signal is applied to a charge pump 38, which produces an output which is representative of the accumulated phase difference between the two input signals of the phase detector 34.

The output from the charge pump 38 is applied to a low-pass filter 40, and then to a voltage controlled oscillator 42, such that any accumulated phase difference between the two input signals of the phase detector 34 tends to alter the frequency of the output from the voltage controlled oscillator 42. This output from the voltage controlled oscillator 42 is then used as the clock signal, which is output from the phase-locked loop 36, and is fed back to the second input of the phase detector 34. The phase-locked loop 36 therefore acts to lock the clock signal to the average phase of its input signal.

Since a function of the preprocessor 32 is to divide the frequency of its input signal by 2, as described in more detail below, the clock signal is therefore half of the data rate of the original input signal. For example, in the case of an input signal with a data rate of 10 Gb/s, the clock signal has a frequency of 5 GHz.

The clock signal is also supplied to a decision block 44, which also receives an intermediate output from the preprocessor circuit 32, as discussed in more detail below. The clock signal determines the timing at which the decision block 44 samples the output from the preprocessor circuit 32, in order to produce a data recovery output signal. Since the clock signal has a frequency of 5 GHz, while the input signal has a data rate of 10 Gb/s, the input signal must be sampled at both edges of the clock signal (i.e. twice per clock cycle). The clock signal may also be supplied to a further circuit output 46, for use in further circuitry, as required.

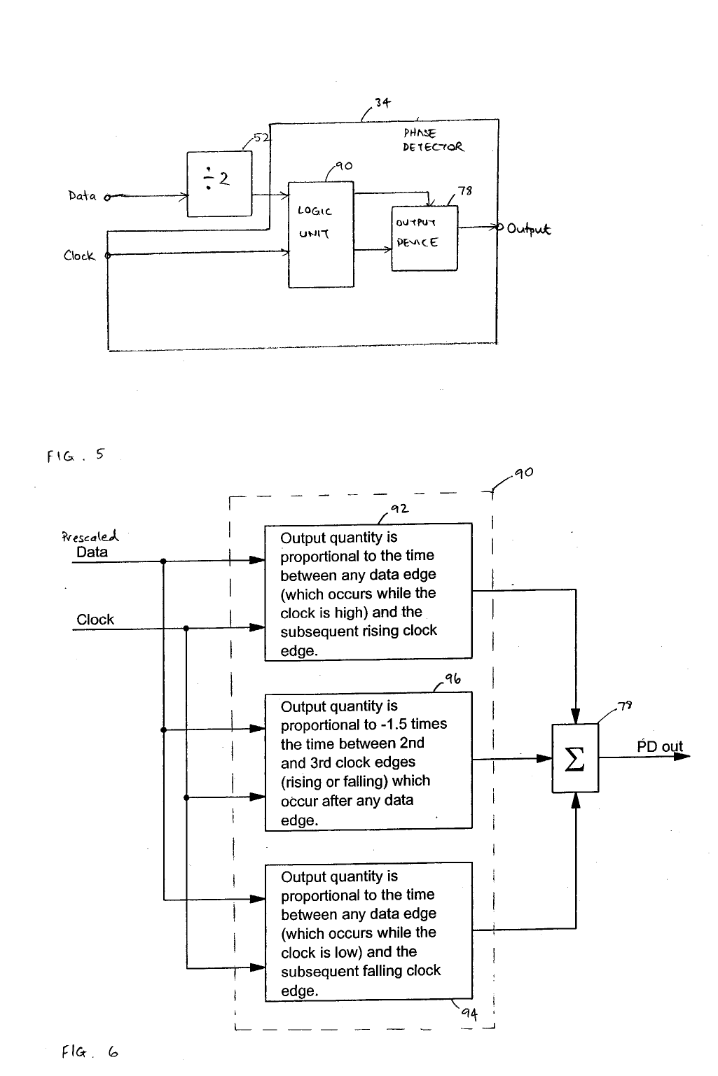

FIG. 4 is a block schematic diagram of the preprocessor 32. The input signal, namely the distorted received data signal, is applied to a limiting amplifier 50, which amplifies the signal, and then provides an output which indicates whether the input is higher or lower than a threshold. The effect of this is to provide a signal which has the same structure of high and low values, but with faster transitions between the two levels. This avoids many of the consequences of the spreading effect, mentioned above.

The output from the limiting amplifier 50 is supplied to a prescaler 52, which is formed from a pair of latches 54, 56 in a conventional way to form a frequency divide-by-2 circuit.

The effect of the prescaler 52 is to divide the frequency of the input signal by 2. Specifically, the prescaler 52 produces an output which changes level only on each rising edge (or alternatively on each falling edge) of its input. This counteracts the effects of duty cycle distortion in the input signal.

The output signal from the prescaler 52 is passed to the data input of the phase detector 34, which is shown in more detail in FIGS. 5, 6 and 7. It will be appreciated that, although the pre-processor 32 and phase detector 34 are shown separately in FIG. 3, this division is only for ease of illustration, since these elements, together with other elements of the phase-locked loop 46, are preferably integrated in a single device.

FIG. 5 shows schematically the functional blocks of the prescaler and the phase detector. Specifically, a data signal, namely the output from the limiting amplifier 50, is applied to the prescaler 52, as discussed above. The modified data signal, having an output which changes level only on alternate edges of the original data signal, is then supplied to a logic unit 90, which also receives an input clock signal. The logic unit 90 produces a phase dependent output, which is dependent on the relative phases of the clock signal and the input data signal. Specifically, in this embodiment of the invention, the phase dependent output is representative of the time period from an edge in the modified data signal, occurring while the clock signal takes a first value, until the next transition in the clock signal from a second value to the first value. More specifically, in the preferred embodiment, the phase dependent output is made up of a first set of output pulses, whose duration is equal to this time period. The logic unit 90 also produces a second set of pulses, whose duration is dependent on the duration of clock pulses.

The two sets of pulses from the logic unit 90 are passed to an output device 78, and their durations are compared. The output device 78 then produces a phase detector output signal, whose magnitude is therefore dependent on the relative phases of the clock signal and the input data signal.

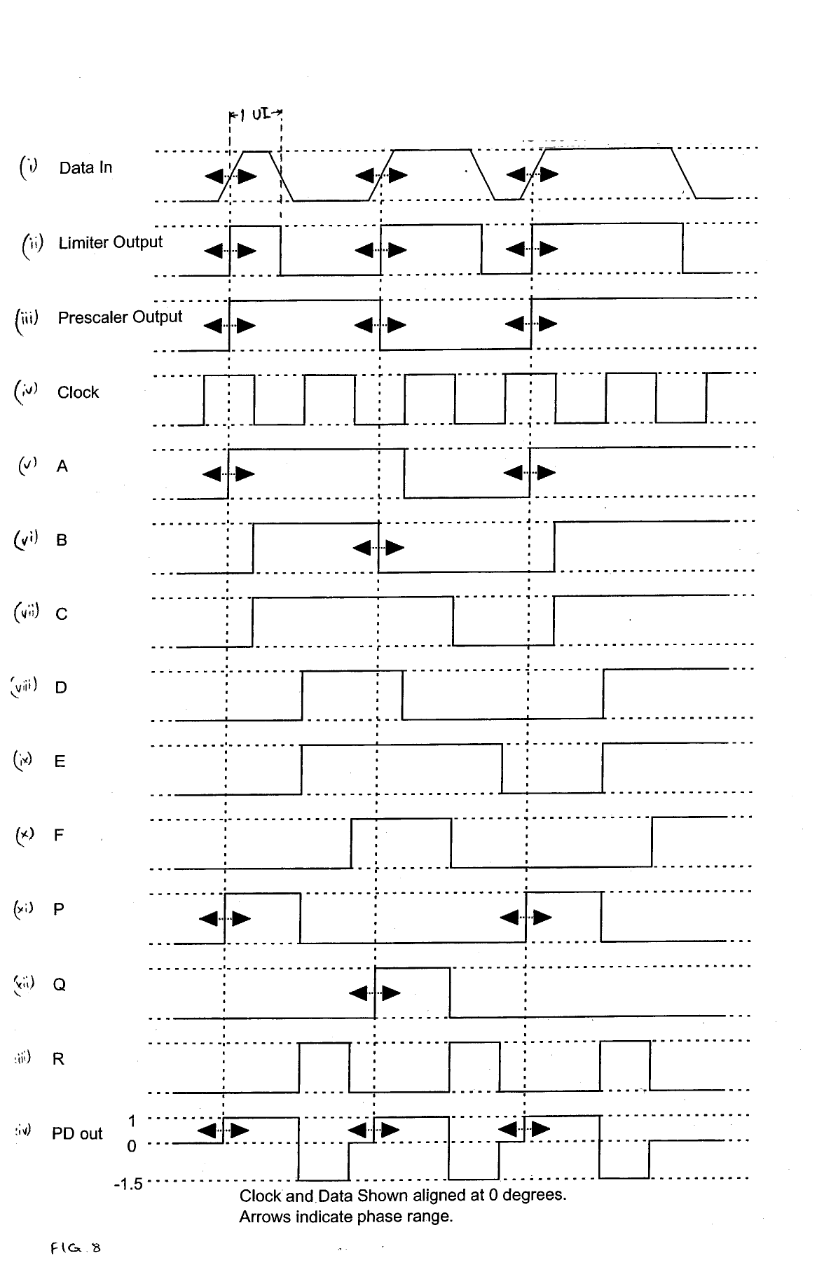

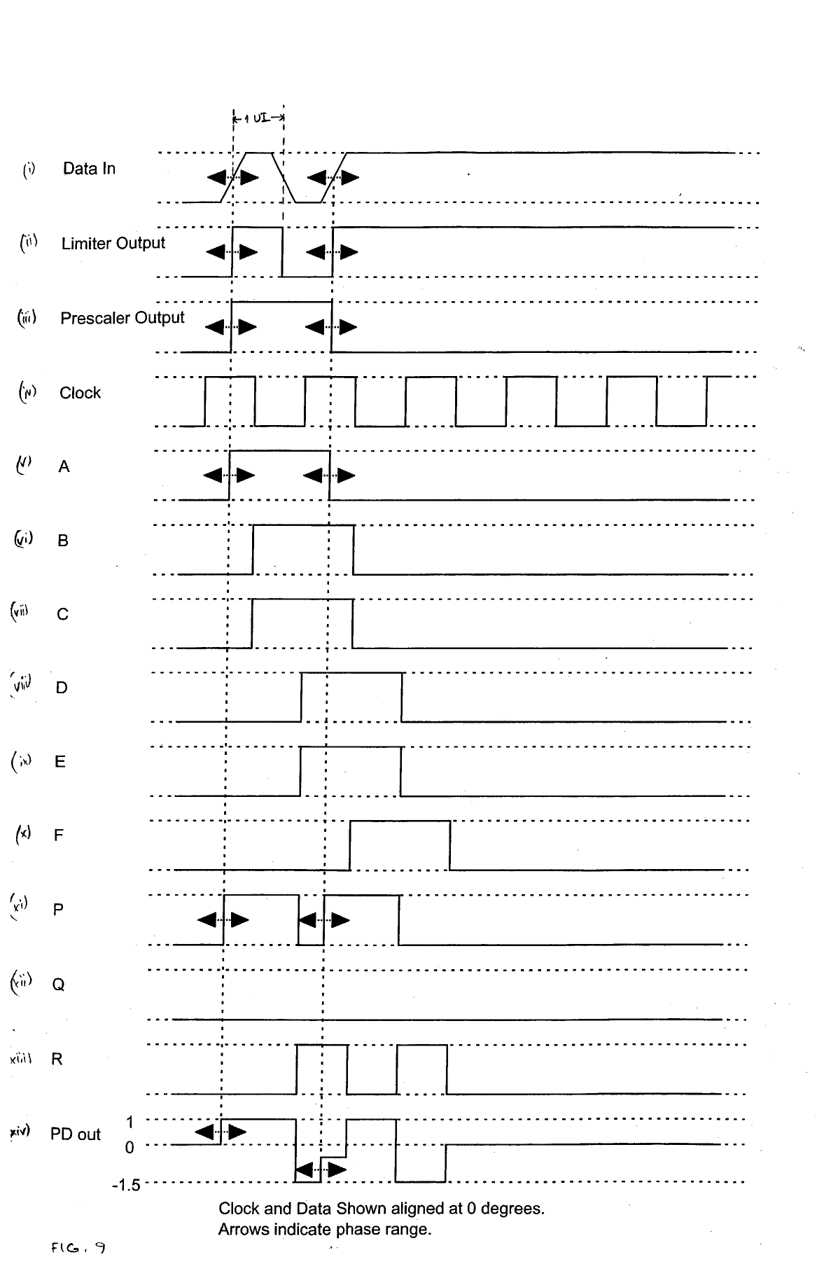

FIG. 6 shows the logical blocks of the logic unit 90 in slightly more detail. The first set of pulses are produced by blocks 92, 94 and include pulses produced by block 92, whose duration corresponds to the time from an edge in the modified data signal, occurring while the clock signal is high, until the next rising edge in the clock signal, and pulses produced by block 94, whose duration corresponds to the time from an edge in the modified data signal, occurring while the clock signal is low, until the next falling edge in the clock signal.

The logic unit also includes a block 96, which produces pulses whose duration is dependent on the duration of clock pulses. More specifically, the block 96 produces one pulse corresponding to each edge in the modified data signal, that is, it produces one pulse each time there is a pulse in the first set of pulses. The pulses in this second set are controlled such that they occur from the second clock signal edge after an edge in the modified data signal, until the next clock signal edge. The magnitudes of these pulses in the second set are then scaled so that, with the data signal and clock signal correctly aligned, the phase detector produces a zero average output when the first and second sets of pulses are summed in the output device 78. The charge pump 38 and filter 40 shown in FIG. 3, or equivalent circuitry, act to produce a signal which corresponds to the average phase detector output, such that with the data signal and clock signal correctly aligned, no adjustment signal is applied to the voltage controlled oscillator 42.

In this case, with the data signal and clock signal being considered correctly aligned when each edge in the data signal occurs in the centre of a clock pulse, and with two blocks 92, 94 producing pulses in response to edges in the modified data signal occurring while the clock signal is high and low respectively, a zero average phase detector output is achieved by inverting the pulses in the second set and increasing their magnitude by a factor of 1.5.

FIG. 7 shows the phase detector 78 in still more detail. The data input signal, that is, the prescaled data input, is passed to first and second latches 62, 64, of which the first latch 62 receives the clock signal inverted, while the second latch 64 receives the clock signal uninverted. The latches 62, 64 are transparent (that is, they output their input signal) when their clock input is low, and they hold their present output when their clock input is high.

The outputs from the first latch 62 and the second latch 64 are passed respectively to third and fourth latches 66, 68, of which the third latch 66 receives the clock signal uninverted, while the fourth latch 68 receives the clock signal inverted. Like the latches 62, 64, the latches 66, 68 are transparent when their clock input is low, and they hold their present output when their clock input is high.

The outputs from the third latch 66 and the fourth latch 68 are passed respectively to fifth and sixth latches 70, 72, of which the fifth latch 70 receives the clock signal inverted, while the sixth latch 72 receives the clock signal uninverted. Again, the latches 70, 72 are transparent when their clock input is low, and they hold their present output when their clock input is high.

The outputs from the fifth latch 70 and the sixth latch 72 are supplied to respective inputs of a first XOR gate 74, the output signal from which is inverted, and multiplied by 1.5 in a multiplier 76, and then supplied to a first input of an adder 78.

The outputs from the first latch 62 and the fourth latch 68 are supplied to respective inputs of a second XOR gate 80, the output signal from which is supplied to a second input of the adder 78. The outputs from the second latch 64 and the third latch 66 are supplied to respective inputs of a third XOR gate 82, the output signal from which is supplied to a third input of the adder 78.

Together, the first, third and fifth latches 62, 66, 70 form a first shift register 84, and the second, fourth and sixth latches 64, 68, 72 form a second shift register 86. The data in these shift registers is clocked by alternate clock edges, such that successive prescaler output bits are passed down alternate shift registers.

The operation of the prescaler 32 and phase detector 34 will now be described in more detail with reference to the timing diagrams of FIG. 6 and FIG. 7.

Specifically, FIGS. 6 and 7 each include the same lines (i)-(xiv), showing the signals at various points in the circuit. FIG. 6 shows as line (i) a Data In line, showing the general shape of the distorted received signal, which is supplied to the pre-processor. Line (ii) shows the form of the output from the limiter 50, for that received signal. Line (iii) then illustrates the form of the output from the prescaler 52, showing that, in this case, the prescaler 52 produces a signal which has a level transition in response to each rising edge in its input signal.

Line (iv) in FIG. 6 shows the form of the clock signal, which is generated by the voltage-controlled oscillator 42. As mentioned above, the clock signal is therefore half of the data rate of the input signal. That is, in the case of an input signal with a data rate of 10 Gb/s, the clock signal has a frequency of 5 GHz.

FIG. 6 shows the situation in which the clock and data are aligned. That is, the phase-locked loop 36 has successfully locked, and a stable situation has been reached, with each data transition in the prescaler output occurring in the centre of a clock pulse. In the situation that the phase-locked loop 36 has not yet correctly locked to the incoming data, many of the signals will be shifted in time relative to the clock signal, and the lengths of the double-headed horizontal arrows in FIGS. 6 and 7 show the extents of the possible phase shifts. These time shifts, or phase errors, can vary in duration from −0.5 UI to +0.5 UI.

Line (v) in FIG. 6 shows the signal at point A, namely the output from the first latch 62. This signal goes high when the prescaler output goes high while the clock signal is high, and goes low when the clock signal next goes high after the prescaler output has gone low.

Line (vi) in FIG. 6 shows the signal at point B, namely the output from the second latch 64. This signal goes high when the clock signal goes low while the prescaler output is high, and goes low when the prescaler output goes low while the clock signal is low.

Line (vii) in FIG. 6 shows the signal at point C, namely the output from the third latch 66. This signal goes high when the clock signal goes low while the signal at point A is high, and goes low when the clock signal next goes low after the signal at point A has gone low.

Line (viii) in FIG. 6 shows the signal at point D, namely the output from the fourth latch 68. This signal goes high when the clock signal next goes high after the signal at point B has gone high, and goes low when the clock signal next goes high after the signal at point B has gone low.

Line (ix) in FIG. 6 shows the signal at point E, namely the output from the fifth latch 70. This signal goes high when the clock signal next goes high after the signal at point C has gone high, and goes low when the clock signal next goes high after the signal at point C has gone low.

Line (x) in FIG. 6 shows the signal at point F, namely the output from the sixth latch 72. This signal goes high when the clock signal goes low while the signal at point D is high, and goes low when the clock signal next goes low after the signal at point D has gone low.

Line (xi) in FIG. 6 shows the signal at point P, namely the output from the second XOR gate 80. This signal produces a pulse that lasts from an edge which occurs in the prescaler output signal while the clock signal is high, until the next rising edge in the clock signal. Line (xii) in FIG. 6 shows the signal at point Q, namely the output from the third XOR gate 82. This signal produces a pulse that lasts from an edge which occurs in the prescaler output signal while the clock signal is low, until the next falling edge in the clock signal.

The durations of the pulses in the signals at points P and Q depend on whether the phase of the clock signal is correctly aligned with the data, as intended. In the situation where correct alignment has been achieved, these pulses each have a duration of 1.5 UI. However, if correct phase alignment has not yet been achieved, the pulses may have durations in the range from 1 UI to 2 UI.

Line (xiii) in FIG. 6 shows the signal at point R, namely the output from the first XOR gate 74. This signal includes a series of pulses, each of which lasts from the second clock edge after an edge in the prescaler output signal, until the third clock edge after that edge in the prescaler output signal. Thus, these pulses are of fixed duration, namely 1 UI.

As is conventional, the phase detector 34 is intended to provide an output level of zero when correct phase alignment is achieved. The signal at point R is therefore scaled by −1.5 (assuming that the XOR gates 74, 76, 78 produce output signals at the same level), and the resulting signal is added to the signals at points P and Q, to give the phase detector output signal, which is shown in line (xiv) of FIG. 6. It will be apparent that, instead, the signal at point R could be left unchanged, and the signals at points P and Q could be scaled appropriately.

As shown in FIG. 3, the phase detector output signal is integrated (by the charge pump 78), filtered (by the low pass filter 80), and used to control the voltage controlled oscillator 82 to adjust the frequency, and hence the phase, of the clock signal. When the phase detector output is zero, the phase of the clock signal remains unchanged. When the phase detector output is positive, the duration of each clock pulse is lengthened until the durations of the pulses at points P and Q become shorter. Conversely, when the phase detector output is negative, the duration of each clock pulse is shortened until the durations of the pulses at points P and Q become longer.

An advantage of this phase detector is that, for most input data patterns, the pulses in the signals at points P and Q have durations in the range from 1 UI to 2 UI. Compared with a circuit in which these pulses have shorter durations, these pulses are less distorted, and can therefore be used more easily in accurate clock recovery.

This feature is illustrated with reference to FIG. 7, which shows the effect of one specific input data pattern 0101, which does not produce this advantageous result. FIG. 7 corresponds generally to FIG. 6, and will not be described in detail. However, it can be seen in line (xi) that the signal at point P contains pulses which have durations between 1 UI and 2 UI, but whose starting points are separated by only 2 UI. In effect, this signal contains a negative pulse between those two pulses, which has a duration of less than 1 UI. There would be a danger that this pulse could be relatively heavily distorted.

However, it is only this input data pattern, and its inverse 1010, which produce this effect. Since these patterns will occur relatively infrequently in random data, the effect of this distortion will be much reduced, compared with a detector in which all pulses have durations of less than 1 UI.

The phase detector shown in FIG. 5 uses two XOR gates 80, 82 to produce pulses whose durations are determined by the clock alignment. An alternative phase detector in accordance with the present invention could include only one of these XOR gates and still operate in essentially the same way.

The phase detector shown in FIG. 5 uses an XOR gate 74 to combine the outputs of two latches 70, 72 to produce pulses of fixed duration. An alternative phase detector in accordance with the present invention could omit the latches 70, 72, and produce pulses of fixed duration by means of an XOR gate connected to the outputs of two latches 66, 68, and still operate in essentially the same way.

There are therefore described a phase detector, and a clock recovery circuit, which provide good performance in the presence of ISI and noise in the input signal.

1. A phase detector, comprising:
an input, for receiving an input data stream, the input data stream having input data transitions;
a divider, for producing a modified input data stream, the modified input data stream having modified input data transitions, and the modified input data transitions corresponding to alternate input data transitions;
a clock signal input, the clock signal alternately taking first and second values, and having clock signal transitions therebetween;
circuitry for producing a phase dependent output, which is representative of a time period from a modified data transition, which occurs while the clock signal takes the first value, until a clock signal transition from the second value to the first value; and
an output device, for comparing the phase dependent output with the duration of pulses in the clock signal.

2. A phase detector as claimed in claim 1, wherein the circuitry for producing a phase dependent output comprises logic circuitry, for producing phase alignment pulses, whose duration is dependent on the time period from a modified data transition, which occurs while the clock signal takes the first value, until a clock signal transition from the second value to the first value.

3. A phase detector as claimed in claim 2, wherein the logic circuitry comprises:
first logic circuitry for producing first phase alignment pulses, whose duration is dependent on the time period from a modified data transition, which occurs while the clock signal is high, until a clock signal transition from low to high; and
second logic circuitry for producing second phase alignment pulses, whose duration is dependent on the time period from a modified data transition, which occurs while the clock signal is low, until a clock signal transition from high to low.

4. A phase detector as claimed in claim 2, wherein the logic circuitry comprises:
third logic circuitry for producing one pulse corresponding to each modified input data transition, each of said pulses having a duration equal to the duration of pulses in the clock signal.

5. A phase detector as claimed in claim 4, wherein the third logic circuitry is adapted to produce pulses which extend from the second clock transition after a modified data transition until the third clock transition after said modified data transition.

6. A phase detector as claimed in claim 4, wherein the output device scales the magnitudes of the pulses whose duration corresponds to the duration of pulses in the clock signal, relative to the phase alignment pulses, such that the phase detector output has an average level of zero when modified data transitions occur exactly half way between successive clock signal transitions.

7. A phase detector as claimed in claim 4, wherein the output device is adapted to invert the pulses whose duration corresponds to the duration of pulses in the clock signal, and increase their magnitude by a factor of 1.5 relative to a magnitude of the phase alignment pulses, and to sum the resulting modified pulses with the phase alignment pulses, such that the phase detector output has an average level of zero when modified data transitions occur exactly half way between successive clock signal transitions.

8. A phase detector as claimed in claim 5, wherein the third logic circuitry comprises:
a first latch, which is connected to receive the modified input data stream and to receive the clock signal inverted,
a second latch, which is connected to receive the modified input data stream and to receive the clock signal uninverted,
a third latch, which is connected to receive an output from the first latch, and to receive the clock signal uninverted,
a fourth latch, which is connected to receive an output from the second latch, and to receive the clock signal inverted,
a fifth latch, which is connected to receive an output from the third latch, and to receive the clock signal inverted,
a sixth latch, which is connected to receive an output from the fourth latch, and to receive the clock signal uninverted, and
a first XOR gate, which is connected to receive outputs from the fifth and sixth latches.

9. A phase detector as claimed in claim 3, wherein the first and second logic circuitry comprise:
a first latch, which is connected to receive the modified input data stream and to receive the clock signal inverted,
a second latch, which is connected to receive the modified input data stream and to receive the clock signal uninverted,
a third latch, which is connected to receive an output from the first latch, and to receive the clock signal uninverted,
a fourth latch, which is connected to receive an output from the second latch, and to receive the clock signal inverted,
a second XOR gate, which is connected to receive outputs from the first latch and the fourth latch, and
a third XOR gate, which is connected to receive outputs from the second latch and the third latch.

10. A clock recovery circuit, comprising:
a limiting amplifier, for receiving an input signal, and for amplifying said received signal with limited output levels, in order to form an input data stream, such that the input data transitions are faster than data transitions in the input signal; and
a phase detector, the phase detector comprising:
an input, for receiving the input data stream;
a divider, for producing a modified input data stream, the modified input data stream having modified input data transitions, and the modified input data transitions corresponding to alternate input data transitions;
a clock signal input, the clock signal alternately taking first and second values, and having clock signal transitions therebetween;
circuitry for producing a phase dependent output, which is representative of a time period from a modified data transition, which occurs while the clock signal takes the first value, until a clock signal transition from the second value to the first value; and
an output device, for comparing the phase dependent output with the duration of pulses in the clock signal.

11. A clock recovery circuit as claimed in claim 10, further comprising:
a charge pump, connected to receive an output signal from the phase detector, and to produce an integrated charge pump output;
a filter, for filtering the integrated charge pump output;
a voltage-controlled oscillator, for receiving an output from the filter, and for producing a clock signal, wherein said clock signal is supplied as an input to the phase detector, such that the clock signal is brought into a desired phase relationship with the input data stream.

12. A clock recovery circuit as claimed in claim 11, further comprising:
a decision circuit, for receiving the input data stream from the limiting amplifier, and for receiving the clock signal, and being adapted to make decisions on the input data stream, at times indicated by the clock signal.

13. A receiver, comprising a clock recovery circuit as claimed in claim 10.
